(19) United States
(12) Patent Application Publication
(10) Pub. No.: US 2025/0040402 A1
(43) Pub. Date: Jan. 30, 2025

(54) Display Apparatus and Transportation Apparatus

(71) Applicant: LG Display Co., Ltd., Seoul (KR)

(72) Inventor: SungSik Son, Paju-si (KR)

(21) Appl. No.: 18/741,230

(22) Filed: Jun. 12, 2024

(30) Foreign Application Priority Data
Jul. 28, 2023 (KR) 10-2023-0098981

(51) Int. Cl. H10K 59/80; B60K 35/22; B60K 37/10; H10K 59/65

(52) U.S. Cl. CPC H10K 59/871; B60K 35/22; B60K 37/10; H10K 59/65

(57) ABSTRACT

A display apparatus includes: a display panel configured to display an image; a front member on the front surface of the display panel; a first support member on the rear surface of the display panel; and a second support member on the rear surface of the first support member, wherein the display panel and the first support member may have a first hole.

### CROSS-REFERENCE TO RELATED APPLICATION

This application claims priority from Republic of Korea Patent Application No. 10-2023-0098981, filed on Jul. 28, 2023, which is hereby incorporated by reference in its entirety.

### BACKGROUND

### Field

Embodiments of the present disclosure relate to a display apparatus and a transportation apparatus including the display apparatus.

### Description of Related Art

As technology advances, display apparatuses may be applied not only to smartphones, laptops, and the like, but also to transportation apparatuses, including automobiles.

Display apparatuses that are widely used may provide, in addition to image display functions, shooting functions and various sensing functions. For this purpose, the display apparatuses are equipped with optical modules such as cameras and sensors.

Accordingly, an optical module is disposed at the edge of the display panel of a display apparatus in order to include the optical module in the display apparatus. Thus, the display apparatus including the optical module has a problem in that has to be large in size due to the physical size of the optical module. For this reason, there have been significant limitations in designing display apparatuses for use in various applications.

### SUMMARY

An object to be achieved by an embodiment of the present disclosure is to provide a display apparatus in which the width of the non-display area of a display panel may be reduced by disposing an optical module that overlaps the display panel.

Another object to be achieved by an embodiment of the present disclosure is to provide a display apparatus in which an optical module is stably coupled by disposing a structure to which the optical module is coupled.

Objects of the present disclosure are not limited to the problems mentioned above, and other problems not mentioned above will be clearly understood by those skilled in the art from the following description.

A display apparatus according to one or more embodiments of the present disclosure may include: a display panel configured to display an image; a front member on the front surface of the display panel; a first support member on the rear surface of the display panel; and a second support member on the rear surface of the first support member. The display panel and the first support member may have a first hole.

According to the present disclosure, there is provided a display apparatus having a hole formed in a display panel and including an optical module-supporting structure around the hole formed in the display panel. As the optical module-supporting structure is disposed around the hole formed in the display panel and the optical module is coupled to the optical module-supporting structure around the hole formed in the display panel, the optical module may be formed to overlap the display panel. Accordingly, the non-display area (or bezel area) of the display panel may be reduced in size.

According to the present disclosure, there may be provided a display apparatus in which an optical module is stably coupled by disposing a structure to which the optical module is coupled.

According to the present disclosure, the fastening structure for fastening the optical module (e.g., a light-receiving device such as a camera, a sensor, etc.) to the display apparatus may be unified (integrated) with the support structure for supporting the rear surface of the display panel, thereby simplifying the structure of the display apparatus and reducing the number of components. Accordingly, it is possible to provide a display apparatus capable of process optimization and weight reduction, and the effect of uni-materialization is obtained.

Effects of the present disclosure are not limited to the effects mentioned above, and other effects not mentioned above will be clearly understood by those skilled in the art from the following description.

### BRIEF DESCRIPTION OF DRAWINGS

FIG. 1 shows the interior space of a transportation apparatus according to one embodiment of the present disclosure.

FIG. 2 shows the interior space of a transportation apparatus according to another embodiment of the present disclosure.

FIG. 3 shows the interior space of a transportation apparatus according to still another embodiment of the present disclosure.

FIG. 4 is an exploded perspective view of a display apparatus according to an embodiment of the present disclosure.

FIG. 5 is a front view of the display apparatus according to an embodiment of the present disclosure.

FIG. 6 is a rear view of the display apparatus according to an embodiment of the present disclosure.

FIG. 7 shows a fastening structure in the display apparatus according to an embodiment of the present disclosure.

FIGS. 8 and 9 show a fastening structure for an optical module according to an embodiment of the present disclosure.

FIG. 10 is a sectional view of the display apparatus according to an embodiment of the present disclosure.

FIG. 11 is a sectional view of the display area in the display apparatus according to an embodiment of the present disclosure.

FIG. 12 shows the structure of an organic light-emitting element in the display apparatus according to an embodiment of the present disclosure.

### DETAILED DESCRIPTION

Advantages and features of the present disclosure, and implementation methods thereof will be clarified through the following embodiments described with reference to the accompanying drawings. The present disclosure may, however, be embodied in different forms and should not be construed as being limited to the embodiments set forth herein. Rather, these embodiments are provided so that this disclosure will be thorough and complete, and will fully convey the scope of the present disclosure to those skilled in the art. Furthermore, the present disclosure is only defined by scopes of claims.

In addition, the shapes, sizes, ratios, angles, numbers, and the like illustrated in the drawings for describing embodiments of the present disclosure are merely examples, and thus the present disclosure is not limited thereto. Like reference numerals refer to like elements throughout the specification. In the following description, when the detailed description of the relevant known technology is determined to unnecessarily obscure the subject matter of the present disclosure, the detailed description will be omitted.

The terms, such as “including,” “having,” “containing,” “composed of,” “consisting of,” or the like, used herein are generally intended to allow other components to be added unless the terms are used with the term “only”. Singular forms used herein are intended to include plural forms unless the context clearly indicates otherwise.

In interpreting any elements or features of the embodiments of the present disclosure, it should be considered that any dimensions and relative sizes include a tolerance or error range even when a specific description is not conducted.

Spatially relative terms, such as “on,” “over,” “above,” “below,” “under,” “beneath,” “lower,” “upper,” “near,” “close,” “adjacent,” or the like, used herein to describe one element or feature's relationship to another element(s) or feature(s) are generally intended to allow one or more additional elements to be interposed between the elements unless the terms, such as “directly,” “immediately,” or the like, are used.

When the terms, such as “first,” “second,” or the like, are used herein to describe various elements or components, it should be considered that these elements or components are not limited by these terms. These terms are merely used herein for distinguishing an element from other elements. Therefore, a first element mentioned below may be a second element in a technical concept of the present disclosure.

Like reference numerals refer to like elements throughout the specification.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other, or may be carried out together in co-dependent relationship.

The term “display apparatus” as used herein may include a display apparatus in a narrow sense, such as a liquid crystal module (LCM), an organic light emitting display module (OLED Module), a quantum dot module, or the like, which includes a display panel and a driver for driving the display panel. The term “display apparatus” may also include a notebook computer, a television, a computer monitor, equipment displays, including an automotive display or other displays for vehicles, a set electronic apparatus or a set device or set apparatus such as a mobile electronic apparatus, e.g., a smartphone, an electronic pad, etc., which are complete products or final products including the LCM, the OLED module, the QD module, or the like.

Accordingly, the term “display apparatus” as used herein may include a display apparatus itself in a narrow sense, an application product including a display apparatus in a narrow sense, or even a set apparatus that is an apparatus for end consumers. Hereinafter, embodiments of the present disclosure will be described in detail with reference to the accompanying drawings.

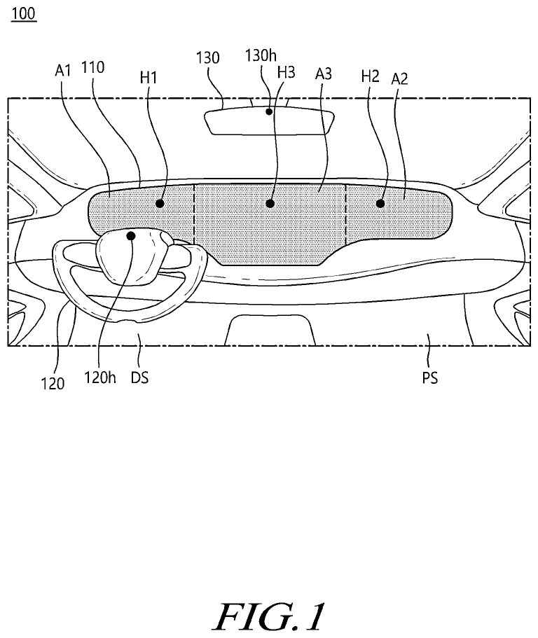

FIG. 1 shows the interior space of a transportation apparatus according to one embodiment of the present disclosure.

The transportation device according to an embodiment of the present disclosure may include a vehicle, etc., but embodiments of the present disclosure are not limited thereto. The present disclosure will be described by way of example of a vehicle.

Referring to FIG. 1, the interior space 100 may include a driver's seat DS, a passenger seat PS, a dashboard 110, a steering wheel 120, and a rearview mirror 130.

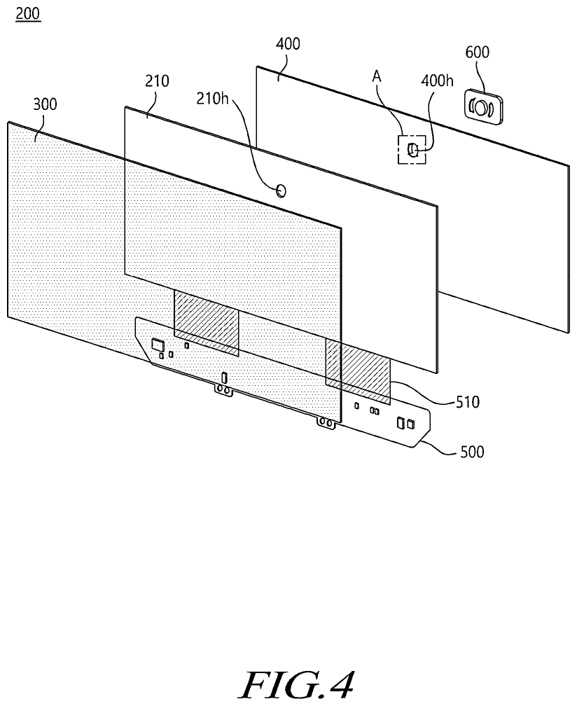

The dashboard 110 may include a first area A1 corresponding to the driver's seat (DS) space, a second area A2 corresponding to the passenger seat (PS) space, and a third area A3 corresponding to a space between the driver's seat DS and the passenger seat PS. Each area of the dashboard 110 may include at least one display apparatus 200 shown in FIG. 4. For example, the display apparatus 200 may be installed in the dashboard 110 of the transportation apparatus. The display apparatus 200 installed in the dashboard 110 may provide driving and other information to each of the driver and passenger.

Accordingly, the areas of the dashboard 110 may have different sizes. As the areas of the dashboard 110 have different sizes, the user of the transportation apparatus may optimally use the transportation apparatus. The first area A1 and second area A2 of the dashboard 110 may be smaller than the third area A3 of the dashboard 110. The display apparatus 200 installed in the dashboard 110 may have a curved outer portion. The dashboard 110 may have a T-shape. When the dashboard 110 has a T-shape, a user sitting in the back seat of the transportation apparatus may better see the display apparatus 200 of the dashboard 110.

The display apparatus 200 corresponding to each area of the dashboard 110 may have a hole therein. The display apparatus 200 may include an optical module. The hole in the display apparatus 200 may serve as a path through which an optical module disposed on the rear surface of the display apparatus 200 emits or receives light. The dashboard 110 may include a first hole H1 in the first area A1, a second hole H2 in a second area A2 different from the first area A1, and a third hole H3 in a third area A3 between the first area A1 and the second area A2.

In addition to the dashboard 110, the steering handle 120 and the rearview mirror 130 may have a handle hole 120h and a rearview mirror hole 130h, respectively.

The display apparatus 200 installed in the dashboard 110 may include an instrument panel, which corresponds to the driver's seat DS and displays various instruments necessary for driving, and a center fascia and a center information display (CID), which are located between the areas corresponding to the driver's seat DS and the passenger seat PS and provide various information to the driver and passenger, but embodiments of the present disclosure are not limited thereto.

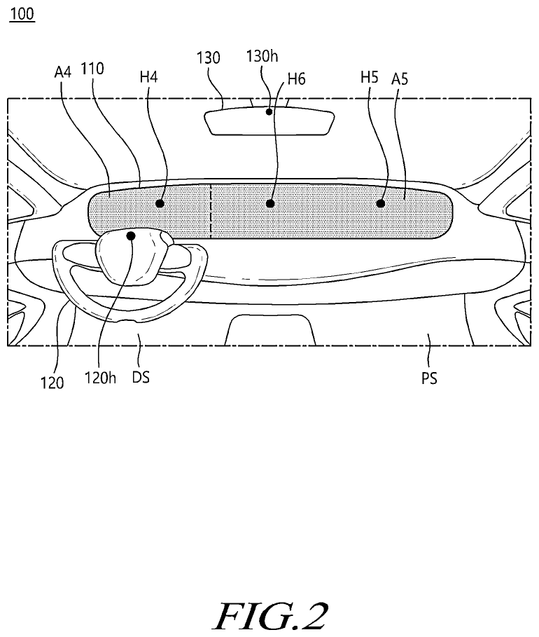

FIG. 2 shows the interior space of a transportation apparatus according to another embodiment of the present disclosure.

Referring to FIG. 2, a dashboard 110 may include a fourth area A4 corresponding to a driver's seat (DS) space, and a fifth area A5 corresponding to a space between the driver's seat DS and the passenger seat PS and to a passenger seat (PS) space. The fourth area A4 may be smaller than the fifth area A5.

A display apparatus 200 (see FIG. 4) corresponding to the fourth area A4 may have a fourth hole H4. A display apparatus 200 (see FIG. 4) corresponding to the fifth area A5 may have a fifth hole H5 and a sixth hole H6. For example, the display apparatus 200 may have one or more holes. If the display apparatus 200 has one or more holes, a single display apparatus 200 may be used by a plurality of users of the transportation apparatus, and thus the display apparatus 200 may be manufactured with a large area. In one embodiment, the dashboard 110 may include a single display apparatus 200 corresponding to both the driver space and the passenger space. For example, the display apparatus 200 may be disposed integrally in the dashboard 110 without distinction between the fourth area A4 and the fifth area A5.

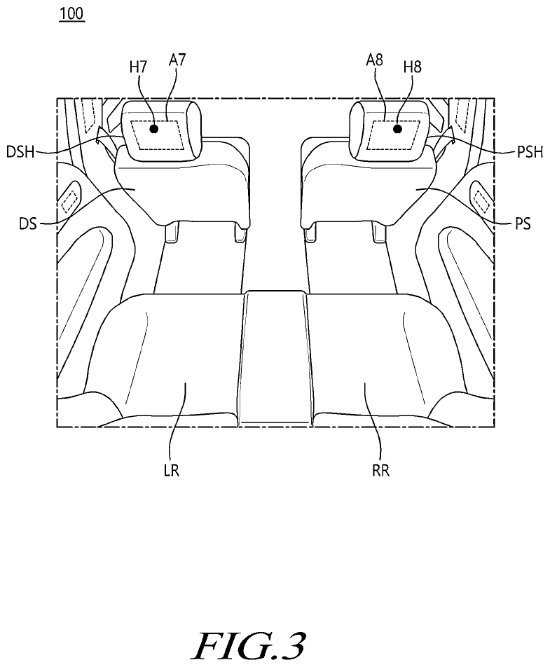

FIG. 3 shows the interior space of a transportation apparatus according to still another embodiment of the present disclosure.

Referring to FIG. 3, the interior space 100 of the transportation apparatus may include a seventh area A7 corresponding to the rear of the headrest DSH of a driver's seat DS, and an eighth area A8 corresponding to the rear of the headrest PSH of a passenger seat PS. A display apparatus 200 (see FIG. 4) corresponding to the seventh area A7 may have a seventh hole H7, and a display apparatus 200 (see FIG. 4) corresponding to the eighth area A8 may have an eighth hole H8. The display apparatus 200 corresponding to the seventh area A7 or the eighth area A8 may provide various information to a user sitting in a left rear seat LR or a right rear seat RR.

The embodiments described above are not limited to what is disclosed in the present disclosure. For example, although FIG. 3 shows each of the display apparatus 200, which includes the seventh hole H7 and corresponds to the seventh area A7, and the display apparatus 200, which includes the eighth hole H8 and corresponds to the eighth area A8, it is possible to contemplate a single display apparatus 200 that includes both the seventh area A7 corresponding to the rear of the driver's seat DS and the eighth area A8 corresponding to the rear of the passenger seat PS.

Each of the first to eighth holes H1 to H8 may be an area through which an optical module is fastened to the lower portion of a display panel 210 shown in FIG. 4. The optical module will be described later with reference to FIG. 4. The first to eighth holes H1 to H8 may have the same size and shape, or at least one of the size and shape may be different therebetween. For example, the first to eighth holes H1 to H8 may have the same or substantially the same fastening structure by which the optical module is fixed (fastened) to the lower portion of the display panel 210. In the following description, the optical module-fastening structure related to the first hole H1 will be described by way of example of the first hole H1 among the first to eighth holes H1 to H8.

FIG. 4 is an exploded perspective view of a display apparatus according to an embodiment of the present disclosure.

Referring to FIG. 4, the display apparatus 200 may include a display panel 210, a front member 300, a first support member 400, a printed circuit board 500, and a flexible film 510.

The flexible film 510 may be bonded to one surface of the display panel 210. The flexible film 510 may include various components disposed on a flexible base film and supply signals to pixels and driving components in the display panel 210. The flexible film 510 may electrically connect the printed circuit board 500 to the display panel 210.

The display panel 210 may include a display area, which displays an image, and a non-display area around the display area.

The printed circuit board 500 is a component that supplies signals to a driver integrated circuit (IC), and various components for supplying various signals to the driver IC may be disposed in the printed circuit board 500. The printed circuit board 500 may be connected to the display panel 210 through the flexible film 510, and may be disposed at one side of the display panel 210 as shown in FIG. 4. Alternatively, the printed circuit board 500 may be disposed on the rear surface of the display panel 210 through the bent flexible film 510.

Although FIG. 4 shows two flexible films 510 and one printed circuit board 500, embodiments of the present disclosure are not limited thereto and the number of flexible films 510 and printed circuit boards 500 may vary depending on the design.

The first support member 400 may be disposed on the rear surface of the display panel 210. The first support member 400 may serve to support or protect the display panel 210 on the rear surface of the display panel 210. Since the first support member 400 has a shape that corresponds to the planar shape of the display panel 210, it may cover the display panel 210.

The first support member 400 may be made of a material that is rigid and has high thermal conductivity. For example, the first support member 400 may be made of a metal material, such as aluminum (Al), copper (Cu), zinc (Zn), silver (Ag), gold (Au), iron (Fe), steel use stainless (SUS), or Invar, or a plastic material, but embodiments of the present disclosure are not limited thereto.

The optical module 600 may be disposed on the rear surface of the first support member 400. The optical module 600 may be any component that performs functions using light. For example, the optical module 600 may be a camera module. However, embodiments of the present disclosure are not limited thereto, and the optical module 600 may also be an illumination sensor, a fingerprint sensor, or the like.

The display panel 210 may have a (1-1) hole 210h, and the first support member 400 may have a (1-2) hole 400h.

The (1-1) hole 210h and the (1-2) hole 400h may overlap each other. The size of the (1-1) hole 210h and the size of the (1-2) hole 400h may be the same. Alternatively, the size of the (1-1) hole 210h and the size of the (1-2) hole 400h may be different from each other in order to maximize the function of the optical module 600 disposed on the rear surface of the first support member 400.

The front member 300 may be disposed on the front surface of the display panel 210. The front member 300 may serve to protect the display panel 210 from external shock and may be permeable to light emitted from the display panel 210. The front member 300 may be disposed to overlap the display panel 210 and to cover the entire surface of the display panel 210. The front member 300 may be a cover glass, a window cover, or a cover window, but embodiments of the present disclosure are not limited thereto.

The front member 300 may serve to protect the display panel 210. In order to maintain the rigidity of the front member 300 and prevent the display panel 210 from being exposed to the outside, holes such as the (1-1) hole 210h and the (1-2) hole 400h may not be included, but embodiments of the present disclosure are not limited thereto. For example, the front member 300 may have holes overlapping the (1-1) hole 210h and the (1-2) hole 400h in order to maximize the performance of the optical module 600 disposed on the rear surface of the display panel 210.

The light that passes through the (1-1) hole 210h and the (1-2) hole 400h may include at least one of visible light, infrared light, and ultraviolet light, but embodiments of the present disclosure are not limited thereto.

Due to the nature of a transportation apparatus, the display panel 210 included in the transportation apparatus may be likely to be exposed to an environment with high temperature or humidity or to undergo repeated physical shock over a long period of time. For this reason, the display panel 210 and front member 300 included in the transportation apparatus may be made of a stretchable and/or shrinkable material. Further, the elongation of the display panel 210 may be the same as the elongation of the front member 300, but embodiments of the present disclosure are not limited thereto.

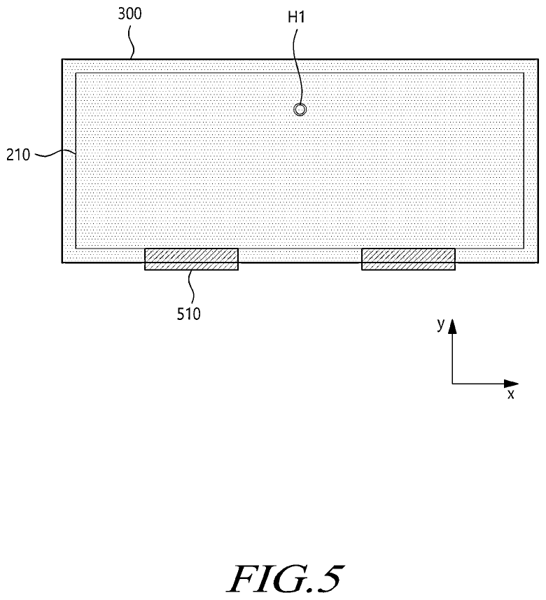

FIG. 5 is a front view of the display apparatus according to an embodiment of the present disclosure.

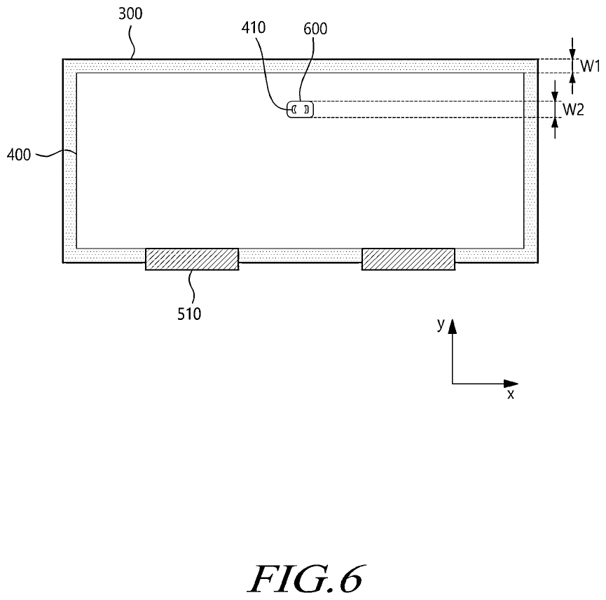

FIG. 6 is a rear view of the display apparatus according to an embodiment of the present disclosure.

Referring to FIG. 5, the display apparatus 200 may include a display panel 210 and a front member 300. The display panel 210 may completely overlap the front member 300. For example, the size of the front member 300 may be larger than the size of the display panel 210.

The display apparatus 200 may have a first hole H1. Although the present disclosure has been described by way of example of the display apparatus 200 disposed in the first area A1, embodiments of the present disclosure are not limited thereto.

As shown in FIG. 4, the first hole H1 may include a (1-1) hole 210h and a (1-2) hole 400h. As shown in FIG. 5, when viewed from the front view, the first hole H1 may be formed at the center of the display panel 210 with respect to the x-direction of the display panel 210, or may be formed close to one edge of the display panel 210 with respect to the length direction of the display panel 210. For example, the first hole H1 may be formed at a position that corresponds to the center of the display panel with respect to the first direction (x-direction) of the display panel 210 and is close to one edge of the display panel 210 with respect to the second direction (y-direction) of the display panel 210. However, the position of the first hole H1 is not limited thereto.

As shown in FIG. 2, when a plurality of holes H5 and H6 are formed in the display apparatus 200 disposed in the fifth area A5 of the dashboard 110, the plurality of holes H5 and H6 in the display apparatus 200 may be formed at positions close to one edge of the display apparatus 200. The position of at least one hole formed in the display apparatus 200 may be designed and changed so that a user of the transportation apparatus may easily use the display apparatus 200.

Referring to FIG. 6, the optical module 600 may be disposed on the rear surface of the first support member 400. The optical module 600 may be disposed to overlap the first hole H1 shown in FIG. 5. For example, the optical module 600 may be disposed to overlap at least one of the display panel 210, the front member 300, and the first support member 400.

The size of the front member 300 may be larger than the size of the display panel 210 and the size of the first support member 400. Thus, due to the difference between the size of the front member 300 and the size of each of the display panel 210 and the first support member 400, the front member 300 may have an edge width W1. The edge width W1 of the front member may have a value greater than 0.

As the edge width W1 of the front member increases, the proportion of the image display area of the display panel 210 in the display apparatus 200 may decrease. As a result, the size of the bezel of the display apparatus 200 may increase.

When the optical module 600 is disposed at a position close to one edge of the display panel 210, the display apparatus 200 may require a bezel having a width approximately equal to the width W2 of the optical module 600 in order to dispose the optical module 600. Accordingly, the front member 300 may have an edge width W1 approximately equal to the width W2 of the optical module 600. For example, the front member 300 may have the edge width W1 corresponding to the width W2 of the optical module 600.

As in the embodiment of the present disclosure shown in FIG. 6, when the optical module 600 is disposed to completely overlap the display panel 210 or the first support member 400, the display apparatus 200 may have a bezel corresponding to the edge width W1 of the front member 300 regardless of the width W2 of the optical module 600. The edge width W1 of the front member 300 may be smaller than the width W2 of the optical module 600. Accordingly, the display apparatus 200 may have a narrow bezel when the optical module 600 overlaps the display panel 210.

The optical module 600 may be disposed to correspond to the number of holes formed in the display panel 210 when viewed from the top view. As shown in FIG. 2, when a plurality of holes H5 and H6 are formed in the display apparatus 200 disposed in the fifth area A5 of the dashboard 110, a plurality of the optical modules 600 may be disposed to correspond to the plurality of holes H5 and H6, but embodiments of the present disclosure are not limited thereto.

The flexible film 510 may be bent to connect the display panel 210 to the printed circuit board 500. The width of the bent flexible film 510 may be smaller than the edge width W1 of the front member 300.

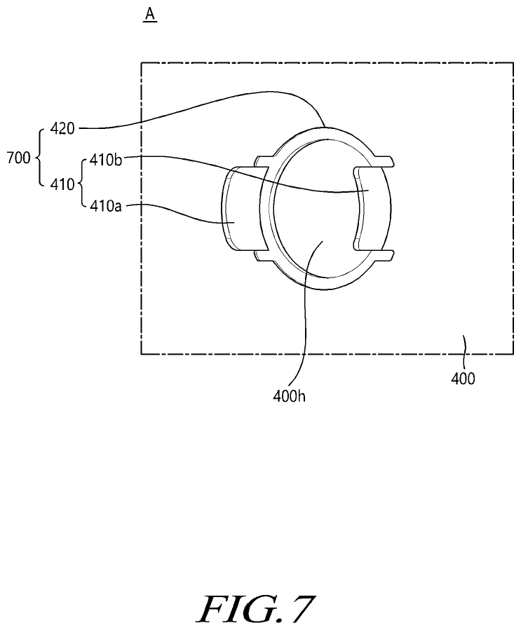

FIG. 7 shows a fastening structure in the display apparatus according to an embodiment of the present disclosure.

Referring to FIG. 7, a rear view of the area A of the display apparatus 200 shown in FIG. 4 is shown. The display apparatus 200 may include a second support member 700 on the rear surface of the first support member 400. The second support member 700 may serve to support the optical module 600.

The second support member 700 may be made of the same material as the first support member 400. The second support member 700 may be formed integrally with the first support member 400.

The first support member 400 may have a (1-2) hole 400h. A receiving member 420 may be formed around the (1-2) hole 400h. The size of the receiving member 420 may be the same as the size of the (1-2) hole 400h, without being limited thereto.

The second support member 700 may include a rib 410 and a receiving member 420, which are located around the (1-2) hole 400h.

The receiving member 420 serve to support the rib 410 coupled to the receiving member 420 and firmly fix the rib 410. The receiving member 420 may be formed at both sides of the rib 410 to fix the rib 410.

Referring to FIG. 7, the ribs 410 may include a first rib 410a and a second rib 410b according to one embodiment.

The first rib 410a may be located at one side of the (1-2) hole 400h. The second rib 410b may be located at the other side of the (1-2) hole 400h. The first rib 410a and the second rib 410b may be formed to protrude from the rear surface of the first support member 400. The rib 410 may be formed around the (1-2) hole 400h and may also be formed on the receiving member 420. The rib 410 may be curved to correspond to the receiving member 420 or the (1-2) hole 400h.

Although FIG. 7 shows that the second support member 700 includes two ribs 410a and 410b, but embodiments of the present disclosure are not limited thereto. The rib 410 may be formed to correspond to the structure of the optical module 600 coupled to the rib 410. For example, the second support member 700 may include at least one rib 410 and a receiving member 420 corresponding to the at least one rib 410.

The rib 410 may be formed integrally with the first support member 400. As the rib 410 is formed integrally with the first support member 400, the second support member 700 may be more stably coupled to the first support member 400.

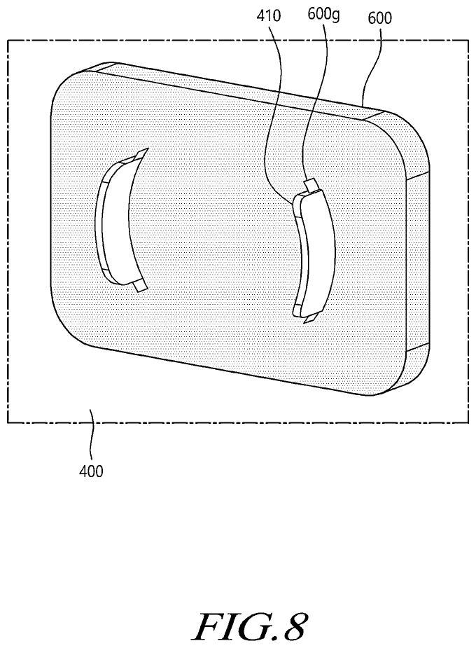

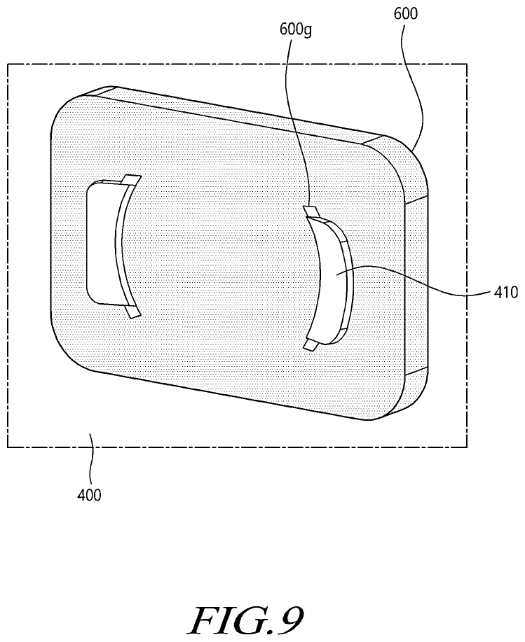

FIGS. 8 and 9 show a fastening structure for an optical module according to an embodiment of the present disclosure.

Referring to FIG. 8, the optical module 600 may be any component that performs functions using light, and may include, for example, a camera module or a sensor, but embodiments of the present disclosure are limited thereto.

The optical module 600 may have a fastening hole 600g. The fastening hole 600g may be disposed to correspond to the rib 410. For example, the fastening hole 600g may have a shape corresponding to that of the rib 410. For example, the fastening holes 600g may be the same in number, shape, or size as the rib 410.

Referring to FIG. 9, the optical module 600 may be coupled to the rib 410 through the fastening hole 600g. The rib 410 may be pressed toward the rear surface of the optical module 600. In this process, the end of the rib 410 may extend in a direction parallel to the first support member 400.

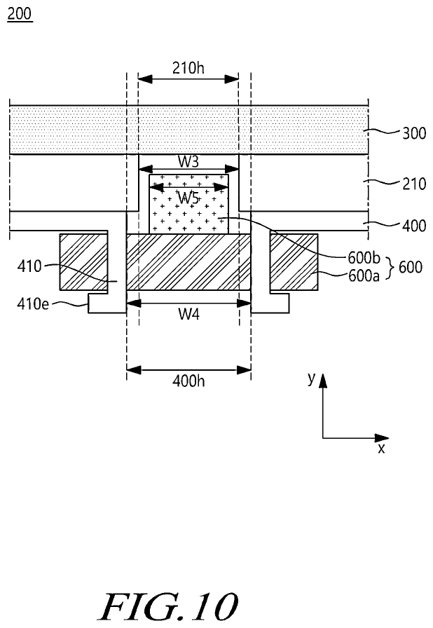

FIG. 10 is a sectional view of the display apparatus according to an embodiment of the present disclosure.

Referring to FIG. 10, the display apparatus 200 may include a front member 300, a display panel 210, a first support member 400, a rib 410, and an optical module 600.

The display panel 210 may be disposed between the front member 300 and the first support member 400. The first support member 400 may be formed integrally with the rib 410, without being limited thereto. The rib 410 may include an extension 410e. The extension 410e may extend outward from the edge of the (1-1) hole 210h and the (1-2) hole 400h. For example, the rib 410 may include an extension 410e that protrudes from the rear surface of the first support member 400 and is bent and extends outward from the edge of the (1-1) hole 210h and the (1-2) hole 400h. As the rib 410 includes the extension 410e, the optical module 600 may be more stably coupled to the display panel 210.

The center of the (1-1) hole 210h may correspond to the center of the (1-2) hole 400h. For example, when each of the (1-1) hole 210h and the (1-2) hole 400h is circular, the (1-1) hole 210h and the (1-2) hole 400h may be concentric with each other.

The display apparatus 200 may have a width W3 of the (1-1 hole) 210h and a width W4 of the (1-2) hole 400h. The width W3 of the (1-1) hole 210h and the width W4 of the (1-2) hole 400h may each be referred to as the size or diameter. The width W3 of the (1-1) hole 210h and the width W4 of the (1-2) hole 400h may be the same as or different from each other.

In order for the display apparatus 200 to have a hole size (e.g., diameter) optimized for the optical module 600, the width W3 of the (1-1) hole 210h and the width W4 of the (1-2) hole (400h) may be different from each other. For example, the width W3 of the (1-1) hole 210h may be smaller than the width W4 of the (1-2) hole 400h.

As the width W3 of the (1-1) hole 210h is smaller than the width W4 of the (1-2) hole 400h, a user may maximally experience the area of the display panel 210 that displays an image in the limited size of the display apparatus 200.

The optical module 600 may include a lower portion 600a and an upper portion 600b. The upper portion 600b may include an area corresponding to the (1-1) hole 210h and the (1-2) hole 400h.

The upper portion 600b may have a width W5. The width W5 of the upper portion 600b may be smaller than the width W3 of the (1-1) hole 210h. When the display apparatus 200 is applied to various applications, the optical module 600 coupled to the display panel 210 through the rib 410 may shake. For example, since a transportation apparatus may be exposed to more diverse environments than when the display apparatus 200 is applied to other applications, it may be required to have higher reliability.

Thus, as the width W5 of the upper portion 600b is smaller than the (1-1) hole 210h, it is possible to prevent or at least reduce a collision between the optical module 600 and the display panel 210, which may occur when the display apparatus 200 moves.

Although FIG. 10 shows that one optical module 600 is disposed on the rear surface of the display panel 210, embodiments of the present disclosure are not limited thereto. For example, the display panel 210 may include the first hole, which includes the (1-1) hole 210h and the (1-2) hole 400h, and a second hole different from the first hole.

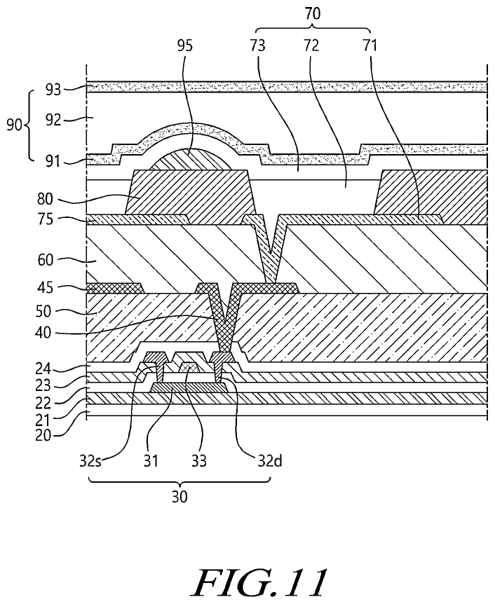

FIG. 11 is a sectional view of the display area in the display apparatus according to an embodiment of the present disclosure.

Referring to FIG. 11, the display apparatus may include a substrate 20. The substrate 20 may be formed over the display area of the display panel and the non-display area adjacent to the display area, and may serve to support and protect components of the display apparatus. The substrate 20 may be made of glass or a flexible material such as polyimide, but embodiments of the present disclosure are not limited thereto. A plurality of substrates 20 may be included, and a dielectric layer may be formed between the plurality of substrates 20.

A buffer layer 21 may be formed on the substrate 20 to protect various components of the display apparatus from the penetration of water and hydrogen from the outside of the substrate 20. The buffer layer 21 may serve to enhance the adhesion between the layers formed on the buffer layer 21 and the substrate 20 and block various types of defects, such as alkaline components, which leak from the substrate 20. The buffer layer 21 may serve to prevent or delay the diffusion of water or oxygen that has penetrated the substrate 20.

The buffer layer 21 may be formed of silicon oxide (SiOx), silicon nitride (SiNx), silicon oxynitride (SiNxOx), or the like, but embodiments of the present disclosure are not limited thereto.

A thin-film transistor 30 including an active layer 31, a gate electrode 33, a source electrode 32s, and a drain electrode 32d may be disposed on the buffer layer 21.

Although FIG. 11 shows only a driving thin-film transistor among various thin-film transistors that may be included in the display apparatus 200, other thin-film transistors such as switching thin-film transistors may also be included in the display apparatus 200.

The active layer 31 may be disposed on the buffer layer 21. The active layer 31 may be formed of amorphous silicon, or polycrystalline silicon, which may be applied to a driving thin-film transistor in a pixel due to its better mobility, lower energy consumption and higher reliability than amorphous silicon, or an oxide semiconductor such as zinc oxide (ZnO) or indium-gallium-zinc oxide (IGZO), which has excellent mobility and uniformity characteristics, but embodiments of the present disclosure are not limited thereto. When the active layer is formed of an oxide semiconductor, it has an excellent effect of blocking leakage current, making it possible to minimize changes in luminance of sub-pixels during low-speed driving.

A first dielectric layer 22 may be disposed on the active layer 31. The first dielectric layer 22 may serve to insulate the active layer 31 and the gate electrode 33. The first dielectric layer 22 may be formed of a inorganic dielectric material such as silicon oxide (SiOx), silicon nitride (SiNx), or silicon oxynitride (SiNxOx), or may be formed of a organic dielectric material, etc., without being limited thereto.

A gate electrode 33 may be disposed on the first dielectric layer 22. The gate electrode 33 may be disposed to overlap the active layer 31.

The gate electrode 33 may be composed of a single layer or multiple layers formed of any one of molybdenum (Mo), copper (Cu), titanium (Ti), aluminum (Al), chromium (Cr), gold (Au), nickel (Ni), neodymium (Nd), and tungsten (W), or an alloy thereof, without being limited thereto.

A second dielectric layer 23 may be disposed on the gate electrode 33. The second dielectric layer 23 may be formed of a inorganic dielectric material such as silicon oxide (SiOx), silicon nitride (SiNx), or silicon oxynitride (SiNxOx), or may be formed of a organic dielectric material, etc., without being limited thereto.

A source electrode 32s and a drain electrode 32d may be disposed on the second dielectric layer 23. The source electrode 32s and the drain electrode 32d may be electrically connected to the active layer 31 via the first and second dielectric layers 22 and 23.

The source electrode 32s and the drain electrode 32d may each be composed of a single layer or multiple layers formed of any one of molybdenum (Mo), copper (Cu), titanium (Ti), aluminum (Al), chromium (Cr), gold (Au), nickel (Ni), and neodymium (Nd), or an alloy thereof, without being limited thereto. For example, the source electrode 32s and the drain electrode 32d may each be composed of a three-layer structure of titanium (Ti)/aluminum (Al)/titanium (Ti), which are conductive metals, without being limited thereto.

A third dielectric layer 24 may be formed on the thin-film transistor 30. The third dielectric layer 24 may serve to protect the thin-film transistor 30. The third dielectric layer 24 may be formed of a inorganic dielectric material such as silicon oxide (SiOx), silicon nitride (SiNx), or silicon oxynitride (SiNxOx), or may be formed of a organic dielectric material, etc. without being limited thereto.

A first protective layer 50 may be formed on the third dielectric layer 24. The first protective layer 50 may be formed of at least one of organic dielectric materials such as acrylic resin, epoxy resin, phenolic resin, polyamide resin, or polyimide resin, without being limited thereto. For example, the first protective layer 50 may be a planarization layer or a dielectric layer, but embodiments of the present disclosure are not limited thereto. A connection electrode 40 may be formed on the first protective layer 50. The connection electrode 40 may serve to electrically connect the organic light-emitting element 70 to the thin-film transistor 30. The connection electrode 40 may be electrically connected to the thin-film transistor 30 via the third dielectric layer 24 and the first protective layer 50. For example, the connection electrode 40 may be electrically connected to the drain electrode 32d of the thin film transistor 30 via the third dielectric layer 24 and the first protective layer 50. A first metal layer 45 may be formed on the same layer as the connection electrode 40.

A second protective layer 60 may be formed on the first protective layer 50. The connection electrode 40 may be formed between the first protective layer 50 and the second protective layer 60.

The second protective layer 50 may be formed of at least one of organic dielectric materials such as acrylic resin, epoxy resin, phenolic resin, polyamide resin, or polyimide resin, without being limited thereto. For example, the second protective layer 60 may be a planarization layer or a dielectric layer, but embodiments of the present disclosure are not limited thereto.

When the first protective layer 50 and the second protective layer 60 are formed of a dielectric material, capacitance may be formed between the metal layers.

An organic light-emitting element 70 including a first electrode 71, a light-emitting layer 72, and a second electrode 73 may be disposed on the second protective layer 60.

The first electrode 71 may be disposed on the second protective layer 60.

The first electrode 71 serves to supply holes to the light-emitting layer 72 and may be formed of a conductive material having a high work function.

When the display apparatus is of a top emission type, the first electrode 71 may a reflective electrode that reflects light, and may be formed of an opaque conductive material.

The first electrode 71 may be formed of at least one of silver (Ag), aluminum (Al), gold (Au), molybdenum (Mo), tungsten (W), chromium (Cr), or alloys thereof, or may also be composed of a three-layer structure of silver (Ag)/palladium (Pd)/copper (Cu), without being limited thereto.

When the display apparatus is of a bottom emission type, the first electrode 71 may be formed of a transparent conductive material that is permeable to light. The first electrode 71 may be formed of at least one of indium tin oxide (ITO) and indium zinc oxide (IZO), but embodiments of the present disclosure are not limited thereto.

The second metal layer 75 may be formed on the same layer as the first electrode 71. The second metal layer 75 may be formed to overlap the first metal layer 45.

A bank 80 may be disposed in some areas on the first electrode 71 and in some areas of the second protective layer 60.

The bank 80 may divide a single pixel into multiple sub-pixels, and may serve to minimize light glare and prevent light mixing occurring at various viewing angles.

The bank 80 may have a bank hole that is disposed in an area excluding the light-emitting area and exposes the first electrode 71.

The bank 80 may be formed of at least one of inorganic dielectric materials, such as silicon nitride (SiNx) or silicon oxide (SiOx), or organic dielectric materials, such as acryl resin, epoxy resin, phenolic resin, or polyamide resin, or polyimide resin, without being limited thereto.

A spacer 95 may be further disposed on the bank 80. The spacer 95 may serve to minimize damage to the display apparatus 200 by external shock.

A light-emitting layer 72 may be disposed on the first electrode 71. The light-emitting layer 72 may be formed of an organic material to emit light of a specific color. The light-emitting layer 72 may be composed of at least one of a red organic light-emitting layer, a green organic light-emitting layer, a blue organic light-emitting layer, and a white organic light-emitting layer. A color filter may be further disposed on the organic light-emitting element 70.

A second electrode 73 may be disposed on the light-emitting layer 72. The second electrode 73 serves to supply electrons to the light-emitting layer 72 and may be formed of a conductive material having a low work function.

When the display apparatus 200 is of a top emission type, the second electrode 73 may be formed of a transparent conductive material that is permeable to light. The second electrode 73 may be formed of at least one of indium tin oxide (ITO) and indium zinc oxide (IZO), without being limited thereto.

When the display apparatus is of a bottom emission type, the second electrode 73 may be a reflective electrode that reflects light, and may be formed of an opaque conductive material. The second electrode 73 may be formed of at least one of silver (Ag), aluminum (Al), gold (Au), molybdenum (Mo), tungsten (W), chromium (Cr), or alloys thereof.

An encapsulation 90 may be disposed on the organic light-emitting element 70. The encapsulation 90 may include a first encapsulation layer 91, a second encapsulation layer 92, and a third encapsulation layer 93, but the number of the encapsulation layers does not limit the content of the present disclosure.

The encapsulation 90 may serve to block the penetration of water or oxygen, and may be formed over the display area and the non-display area.

The first encapsulation layer 91 and the third encapsulation layer 93 may each be formed of at least one inorganic material selected from among the group consisting of silicon nitride (SiNx), silicon oxide (SiOx), or aluminum oxide (AlyOz), but embodiments of the present disclosure are not limited thereto.

The second encapsulation layer 92 may cover foreign substances or particles that may occur during the manufacturing process.

The second encapsulation layer 92 may be formed of a polymer such as silicon oxycarbon (SiOCz), epoxy, polyimide, or polyethylene, without being limited thereto.

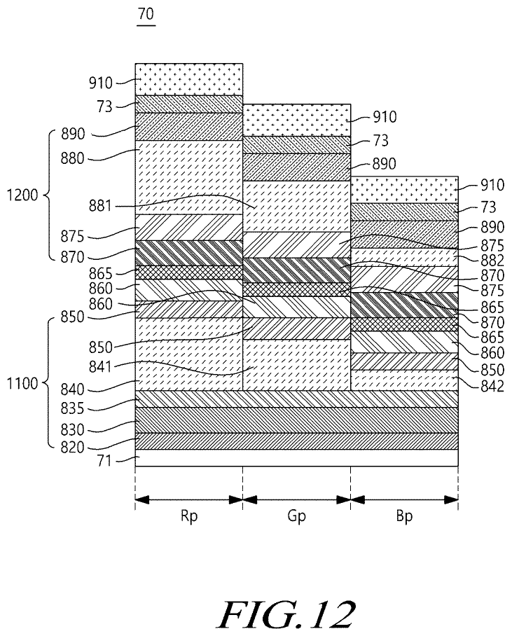

FIG. 12 shows the structure of an organic light-emitting element in the display apparatus according to an embodiment of the present disclosure.

Referring to FIG. 12, the display apparatus may include an organic light-emitting element 70.

The organic light-emitting element 70 may include a first electrode (anode) 71 formed on a substrate in which a red sub-pixel area Rp, a green sub-pixel area Gp, and a blue sub-pixel area Bp are defined, a hole injection layer (HIL) 820, a first hole transporting layer (1^{st} HTL) 830, a first hole control layer (1^{st} HCL) 835, a first organic light-emitting layer composed of a first red light-emitting layer (1^{st} red EML) 840, a first green light-emitting layer (1^{st} green EML) 841, and a first blue light-emitting layer (1^{st} blue EML) 842, a first electron transporting layer (1^{st} ETL) 850, a first charge generation layer (N-CGL) 860, a second charge generation layer (P-CGL) 865, a second hole transporting layer (2^{nd} HTL) 870, a second hole control layer (2^{nd} HCL) 875, a second organic light-emitting layer composed of a second red light-emitting layer (2^{nd} red EML) 880, a second green light-emitting layer (2^{nd} green EML) 881, and a second blue light-emitting layer (2^{nd} blue EML) 882, a second electron transporting layer (2^{nd} ETL) 890, a second electrode (cathode) 73, and a capping layer (CPL) 910.

In addition, the organic light-emitting element 70 according to an embodiment of the present disclosure may be an organic light-emitting element having a two-stack structure in which a first light-emitting unit (1^{st} EL unit) 1100 including the first organic light-emitting layer and a second light-emitting unit (2^{nd} EL unit) 1200 including the second organic light-emitting layer are stacked between the first electrode 71 and the second electrode 73.

For example, in the organic light-emitting element 70 according to an embodiment of the present disclosure, the first light-emitting unit (or first light-emitting part) 1100 includes a hole injection layer 820, a first hole transporting layer 830, a first hole control layer 835, a first organic light-emitting layer composed of a first red light-emitting layer 840, a first green light-emitting layer 841, and a first blue light-emitting layer, and a first electron transporting layer 850.

In the organic light-emitting element 70 according to an embodiment of the present disclosure, the second light-emitting unit (or second light-emitting part) 1200 may include a second hole transporting layer 870, a second hole control layer 875, a second organic light-emitting layer composed of a second red light-emitting layer 880, a second green light-emitting layer 881, and a second blue light-emitting layer 882, and a second electron transporting layer 890.

The organic light-emitting element 70 according to an embodiment of the present disclosure may include a first charge generation layer 860, which is an n-type charge generation layer located between the first light-emitting unit 1100 and the second light-emitting unit 1200, a second charge generation layer 865, which is a p-type charge generation layer.

In the display apparatus including the organic light-emitting element according to an embodiment of the present disclosure, a gate line and a data line that intersect each other to define each pixel area, and a power line that extends parallel to any one of them, are located on the substrate, and a switching thin-film transistor connected to the gate line and data line and a driving thin-film transistor connected to the switching thin-film transistor are located in each pixel area. The driving thin-film transistor may be connected to the first electrode (anode) 71.

The first electrode 71 is located on the substrate so as to correspond to each of the red sub-pixel area Rp, the green sub-pixel area Gp, and the blue sub-pixel area Bp, and may be composed of a reflective electrode.

For example, the first electrode 71 may include a transparent conductive material layer having a high work function, such as indium-tin-oxide (ITO), and a reflective material layer, such as silver (Ag) or a silver (Ag) alloy), but embodiments of the present disclosure are not limited thereto.

The hole injection layer 820 may be located on the first electrode 810 so as to correspond to all of the red sub-pixel area Rp, the green sub-pixel area Gp, and the blue sub-pixel area Bp.

The hole injection layer 820 may serve to facilitate hole injection, and may be formed of any one or more of 1,4,5,8,9,11-hexaazatriphenylene-hexanitrile (HATCN), copper phthalocyanine (CuPc), poly(3,4)-ethylenedioxythiophene (PEDOT), and N,N-dinaphthyl-N,N′-diphenylbenzidine (NPD), without being limited thereto.

The first hole transporting layer 830 and the second hole transporting layer 870 are each formed to correspond to all of the red sub-pixel area Rp, the green sub-pixel area Gp, and the blue sub-pixel area Bp. The first hole transporting layer 830 may be located on the hole injection layer 820, and the second hole transporting layer 870 may be located on the second charge generation layer 865.

The first hole transporting layer 830 and the second hole transporting layer 870 serve to facilitate hole transport, and may be formed of any one or more of N,N-dinaphthyl-N,N′-diphenylbenzidine (NPD), N,N′-bis-(3-methylphenyl)-N,N′-bis-(phenyl)-benzidine (TPD), s-TAD, and 4,4′,4″-tris(N-3-methylphenyl-N-phenyl-amino)-triphenylamine (MTDATA), without being limited thereto.

In the organic light-emitting element 70 according to an embodiment of the present disclosure, the first hole control layer 835 may be located on the first hole transporting layer 830 so as to correspond to all of the red sub-pixel area Rp, the green sub-pixel area Gp, and the blue sub-pixel area Bp.

The second hole control layer 875 may be located on the second hole transporting layer 870 so as to correspond to all of the red sub-pixel area Rp, the green sub-pixel area Gp, and the blue sub-pixel area Bp.

Holes have higher mobility than electrons at high temperatures. The first hole control layer 835 and the second hole control layer 875 may prevent a phenomenon in which holes leave the light-emitting area by moving to the first electron transporting layer 850 and the second electron transporting layer 890 via the first organic light-emitting layer composed of the first red light-emitting layer 840, the first green light-emitting layer 841, and the first blue light-emitting layer 842, and the second organic light-emitting layer composed of the second red light-emitting layer 880, the second green light-emitting layer 881, and the second blue light-emitting layer 882, which are the area in which electrons and holes recombine to emit light. The first hole control layer 835 and the second hole control layer 875 may each be formed of a material such as a carbazole derivative, a triarylamine derivative, or a triamine derivative. For example, the first hole control layer 835 and the second hole control layer 875 may each be formed of any one or more of N,N′-bis(3-methylphenyl)-N,N′-bis(phenyl)-benzidine (TPD), bis[N-(1-naphthyl)-N-phenyl]benzidine (α-NPB), 1,3,5-tris(4-diphenylaminophenyl)benzene (TDAPB), tris(4-carbazoyl-9-yl)triphenylamine (TCTA), spiro-TAD (2,2′,7,7′-tetrakis(N,N-diphenylamino)-9,9-spirobifluorene, 4,4′-bis(carbazol-9-yl)biphenyl (CBP), 4-[bis(9,9-dimethylfluoren-2-yl)amino]phenyl group (BFA-1T), spiro-TCBz (triclabendazole), and TBA, without being limited thereto.

The first hole control layer 835 and the second hole control layer 875 may be formed of the same material selected from among the materials described above, or may be formed of different materials selected from among the materials described above in consideration of the mobility of holes in the first light-emitting unit 1100 and the second light-emitting unit 1200.

The first red light-emitting layer 840 may be located in the red sub-pixel area Rp on the first hole transport layer 830, and the second red light-emitting layer 880 may also be located in the red sub-pixel area Rp on the second hole transporting layer 870. The first red light-emitting layer 840 and the second red light-emitting layer 880 may each include a light emitting material that emits red light, wherein the light emitting material may be formed using a phosphorescent material or a fluorescent material.

For example, the first red light-emitting layer 840 and the second red light-emitting layer 880 may each include a host material including 4,4′-bis(carbozol-9-yl)biphenyl (CBP) or 1,3-bis(N-carbozolyl)benzene (mCP), and may each be formed of a phosphorescent material including a dopant including any one or more of bis(1-phenylquinoline) acetylacetonate iridium (PQIr(acac)), tris(1-phenylquinoline) iridium (PQIr), and octaethylporphyrin platinum (PtOEP). Alternatively, the first red light-emitting layer 840 and the second red light-emitting layer 880 may each be formed of a fluorescent material including PBD:Eu(DBM)3(Phen) or perylene, without being limited thereto.

The first green light-emitting layer 841 may be located in the green sub-pixel area Gp on the first hole transporting layer 830, and the second green light-emitting layer 881 may also be located in the green sub-pixel area Gp on the second hole transporting layer 870. The first green light-emitting layer 841 and the second green light-emitting layer 881 may each include a light-emitting material that emits green light, wherein the light-emitting material may be formed using a phosphorescent material or a fluorescent material.

For example, the first green light-emitting layer 841 and the second green light-emitting layer 881 may each include a host material including CBP or mCP, and may each be formed of a phosphorescent material containing a dopant material, such as an iridium (Ir) complex including tris(2-phenylpyridine)iridium(Ir(ppy)3(fac). Alternatively, the first green light-emitting layer 841 and the second green light-emitting layer 881 may each be formed of a fluorescent material including tris(8-hydroxyquinolino)aluminum (Alq3), without being limited thereto.

The first blue light-emitting layer 842 may be located in the blue sub-pixel area Bp on the first hole transporting layer 830, and the second blue light-emitting layer 882 may also be located in the blue sub-pixel area Bp on the second hole transporting layer 870. The first blue light-emitting layer 842 and the second blue light-emitting layer 882 may each include a light-emitting material that emits blue light, wherein the light-emitting material may be formed using a phosphorescent material or a fluorescent material.

For example, the first blue light-emitting layer 842 and the second blue light-emitting layer 882 may each include a host material including CBP or mCP, and may each be formed of a phosphorescent material containing a dopant material including (4,6-F2ppy)2Irpic, but embodiments of the present disclosure are not limited thereto. In addition, the first blue light-emitting layer 842 and the second blue light-emitting layer 882 may each be formed of a fluorescent material containing any one of spiro-DPVBi, spiro-6P, distyrylbenzene (DSB), distyrylarylene (DSA), PFO-based polymer, and a PPV-based polymer, without being limited thereto.

The first electron transport layer 850 may be located on the first red light-emitting layer 840, the first green light-emitting layer 841, and the first blue light-emitting layer 842 so as to correspond to all of the red sub-pixel region Rp, the green sub-pixel region Gp, and the blue sub-pixel region Bp. The second electron transport layer 890 may be located on the second red light-emitting layer 880, the second green light-emitting layer 881, and the second blue light-emitting layer 882 so as to correspond to all of the red sub-pixel area Rp, the green sub-pixel area Gp, and the blue sub-pixel area Bp.

The first electron transporting layer 850 and the second electron transporting layer 890 may transport and inject electrons, and the thickness of each of the first electron transporting layer 850 and the second electron transporting layer 890 may be determined in consideration of the electron transport characteristics thereof.

The first electron transporting layer 850 and the second electron transporting layer 890 may serve to facilitate electron transport, and may each be formed of any one or more of tris(8-hydroxyquinolino)aluminum (Alq3), 2-(4-biphenylyl)-5-(4-tert-butylpheny)-1,3,4oxadiazole (PBD), TAZ, spiro-PBD, BAlq, and SAlq, without being limited thereto.

It is possible to additionally provide an electron injection layer (EIL) on the second electron transporting layer 890.

The electron injection layer (EIL) may be formed of tris(8-hydroxyquinolino)aluminum (Alq3), 2-(4-biphenylyl)-5-(4-tert-butylpheny)-1,3,4oxadiazole (PBD), TAZ, spiro-PBD, BAlq, or SAlq, without being limited thereto.

Here, the structure is not limited according to the embodiment of the present disclosure, and at least any one of the hole injection layer 820, the first hole transport layer 830, the second hole transporting layer 870, the first electron transporting layer 850, the second electron transporting layer 890, and the electron injection layer (EIL) may also be omitted. In addition, at least any one of two of the first hole transporting layer 830, the second hole transporting layer 870, the first electron transporting layer 850, the second electron transporting layer 890, and the electron injection layer (EIL) may also be composed of two or more layers.

The first charge generation layer 860 may be located on the first electron transporting layer 850 so as to correspond to all of the red sub-pixel region Rp, the green sub-pixel region Gp, and the blue sub-pixel region Bp. The second charge generation layer 865 may be located on the first charge generation layer 860 so as to correspond to all of the red sub-pixel region Rp, the green sub-pixel region Gp, and the blue sub-pixel region Bp. The first charge generation layer 860 and the second charge generation layer 865 may have an N-P junction structure.

Referring to FIG. 12, the first charge generation layer 860 and the second charge generation layer 865 may be located between the first light-emitting unit 1100 and the second light-emitting unit 1200. The first charge generation layer 860 and the second charge generation layer 865 may control the charge balance between the two light-emitting units, that is, the first light-emitting unit 1100 and the second light-emitting unit 1200.

The first charge generation layer 860 may serve as an n-type charge generation layer (n-CGL) that assists the injection of electrons into the first light-emitting unit 1100 located below the first charge generation layer 860. The second charge generation layer 865 may serve as a p-type charge generation layer (p-CGL) that assists the injection of electrons into the second light-emitting unit 1200 located above the second charge generation layer 865.

For example, the first charge generation layer 860, which is an n-type charge generation layer (n-CGL) that serves to inject electrons, may be formed of an alkali metal, an alkali metal compound, or an organic material or a compound thereof that serves to inject electrons. In addition, the host material of the first charge generation layer 860 may be composed of the same material as the material of each of the first electron transport layer 850 and the second electron transport layer 890. For example, it may be composed of a mixed layer in which an organic material such as an anthracene derivative is doped with a dopant such as lithium (Li), without being limited thereto.

The second charge generation layer 865 is located on the first charge generation layer 860. The second charge generation layer 865 serves as a p-type charge generation layer (p-CGL) serving to inject holes, and the host material of the second charge generation layer 865 may be composed of the same material as the material of each of the first hole injection layer 820, the first hole transporting layer 830, and the second hole transporting layer 870. For example, it may be composed of a mixed layer in which an organic material such as 1,4,5,8,9,11-hexaazatriphenylene-hexanitrile (HATCN), cupper phthalocyanine (CuPc), or tris(4-bromophenyl)aluminum hexachloroantimonate (TBAHA) is doped with a p-type dopant, without being limited thereto. Here, the p-type dopant may be composed of any one of F4-TCNQ and NDP-9, without being limited thereto.

The second electrode 73 is located on the second electron transport layer 890 so as to correspond to all of the red sub-pixel area Rp, the green sub-pixel area Gp, and the blue sub-pixel area (Bp). For example, the second electrode 73 may be formed of an alloy of magnesium and silver (Mg:Ag) and may have transflective characteristics. For example, the light emitted from the organic light-emitting layer is emitted to the outside through the second electrode 73, and some of the light is directed back to the first electrode 71 since the second electrode 73 has transflective characteristics.

As such, due to a micro-cavity effect in which repetitive reflection occurs between the first electrode 71 and the second electrode 73, which acts as a reflective layer, light is repeatedly reflected within the cavity between the first electrode 71 and the second electrode 73, thereby increasing light efficiency.

In addition, the first electrode 71 may be composed of a transparent electrode and the second electrode 73 may be composed of a reflective electrode, so that the light from the organic light-emitting layer may be emitted to the outside through the first electrode 71.

The capping layer 910 is located on the second electrode 73. The capping layer 910 may serve to increase the light extraction effect in the organic light emitting element. The capping layer 910 may be composed of any one of the material of the first hole transport layer 830, the material of the second hole transporting layer 870, the material of the first electron transporting layer 850, the material of the second electron transporting layer 890, and the host material of each of the first red light emitting layer 840, the second red light-emitting layer 880, the first green light-emitting layer 841, the second green light-emitting layer 881, the first blue light-emitting layer 842, and the second blue light-emitting layer 882, but the embodiments of the present disclosure are not limited thereto. In addition, the capping layer 910 may be omitted.

A display apparatus according to one or more embodiments of the present disclosure may be described as follows.

A display apparatus according to an embodiment of the present disclosure may include: a display panel configured to display an image; a front member on the front surface of the display panel; a first support member on the rear surface of the display panel; and a second support member on the rear surface of the first support member. The display panel and the first support member may have a first hole.

According to one or more embodiments of the present disclosure, the display apparatus further includes an optical module located on the rear surface of the first support member, the optical module may be disposed to overlap the first hole.

According to one or more embodiments of the present disclosure, the edge width of the front member may be smaller than the width of the optical module.

According to one or more embodiments of the present disclosure, the optical module may include a camera module or a sensor.

According to one or more embodiments of the present disclosure, the second support member may include a rib protruding from the rear surface of the first support member. The rib may be located around the first hole of the first support member.

According to one or more embodiments of the present disclosure, the rib may be formed integrally with the first support member.

According to one or more embodiments of the present disclosure, the rib may include a first rib located at one side of the first hole and a second rib located at the other side of the first hole.

According to one or more embodiments of the present disclosure, the rib may include an extension protruding from the rear surface of the first support member and bent outward from the first hole.

According to one or more embodiments of the present disclosure, the optical module may include a fastening hole corresponding to the rib.

According to one or more embodiments of the present disclosure, the optical module may be coupled to the rib through the fastening hole.

According to one or more embodiments of the present disclosure, the display panel and the first support member may further have a second hole different from the first hole.

According to one or more embodiments of the present disclosure, the display apparatus may be disposed in the dashboard of a transportation apparatus.

According to one or more embodiments of the present disclosure, the dashboard may include a first area and a second area different from the first area.

According to one or more embodiments of the present disclosure, the first hole may include a (1-1) hole and a (1-2) hole, wherein the (1-1) hole and the (1-2) hole may be corresponding to each other and may have the same or different sizes.

According to one or more embodiments of the present disclosure, the second support member may be made of the same material as the first support member.

According to one or more embodiments of the present disclosure, the second support member may further comprise a receiving member for supporting the rib.

According to one or more embodiments of the present disclosure, a width of an area of the optical module corresponding to the first hole may be smaller than a width of the first hole.

According to one or more embodiments of the present disclosure, a transportation device may include a display apparatus within the interior space of a vehicle.

According to one or more embodiments of the present disclosure, the interior space may include a first area corresponding to a driver's seat and a second area corresponding to a passenger seat.

According to one or more embodiments of the present disclosure, the size of the first area and the size of the second area may be different from each other.

According to one or more embodiments of the present disclosure, the interior space may further include a third area between the first area and the second area.

According to one or more embodiments of the present disclosure, the interior space may further include a fourth area located on the rear surface of the headrest of any one of the driver's seat and the passenger seat.

According to one or more embodiments of the present disclosure, the size of the first area or the second area may be different from the size of the third area.

Although the example embodiments of the present disclosure have been described in more detail with reference to the accompanying drawings, the present disclosure is not necessarily limited to these embodiments and may be embodied in many different forms without departing from the technical concept of the present disclosure.

Therefore, the example embodiments of the present disclosure are provided for illustrative purposes only but not intended to limit the technical concept of the present disclosure, and the scope of the technical concept of the present disclosure is not limited by these embodiments. Therefore, it should be understood that the above-described example embodiments are illustrative in all aspects and do not limit the present disclosure. The scope of protection of the present disclosure should be interpreted in accordance with the appended claims, and all technical ideas within the scope equivalent thereto should be interpreted as being included in the scope of rights of the present disclosure.

What is claimed is:

1. A display apparatus, comprising:
a display panel configured to display an image;
a front member on a front surface of the display panel;
a first support member on a rear surface of the display panel; and
a second support member on a rear surface of the first support member,
wherein the display panel and the first support member have a first hole.

2. The display apparatus of claim 1, further comprising:
an optical module on the rear surface of the first support member, the optical module is disposed to overlap the first hole.

3. The display apparatus of claim 2, wherein an edge width of the front member is smaller than a width of the optical module.

4. The display apparatus of claim 2, wherein the optical module comprises a camera module or a sensor.

5. The display apparatus of claim 2, wherein the second support member comprises a rib protruding from the rear surface of the first support member, the rib located around the first hole of the first support member.

6. The display apparatus of claim 5, wherein the rib is integral with the first support member.

7. The display apparatus of claim 5, wherein the rib comprises a first rib located at a first side of the first hole and a second rib located at a second side of the first hole.

8. The display apparatus of claim 7, wherein the rib comprises an extension protruding from the rear surface of the first support member and bent outward from the first hole.

9. The display apparatus of claim 5, wherein the optical module comprises a fastening hole corresponding to the rib.

10. The display apparatus of claim 9, wherein the optical module is coupled to the rib through the fastening hole.

11. The display apparatus of claim 1, wherein the display panel and the first support member include a second hole that is different from the first hole.

12. The display apparatus of claim 1, wherein the display apparatus is installed in a dashboard of a transportation apparatus.

13. The display apparatus of claim 12, wherein the dashboard comprises a first area and a second area that is different from the first area.

14. The display apparatus of claim 1, wherein the first hole comprises a (1-1) hole in the display panel and a (1-2) hole in the first support member, wherein the (1-1) hole and the (1-2) hole are corresponding to each other and have the same or different sizes.

15. The display apparatus of claim 1, wherein the second support member is made of the same material as the first support member.

16. The display apparatus of claim 5, wherein the second support member further comprises a receiving member for supporting the rib.

17. The display apparatus of claim 2, wherein a width of an area of the optical module corresponding to the first hole is smaller than a width of the first hole.

18. A transportation apparatus, comprising:
an interior space; and
the display apparatus of claim 1 in the interior space.

19. The transportation apparatus of claim 18, wherein the interior space comprises a first area corresponding to a driver's seat and a second area corresponding to a passenger seat.

20. The transportation apparatus of claim 19, wherein the first area and the second area have different sizes.

21. The transportation apparatus of claim 19, wherein the interior space further comprises a third area between the first area and the second area.

22. The transportation apparatus of claim 21, wherein the interior space further comprises a fourth area on a rear surface of a headrest of any one of the driver's seat or the passenger seat.

23. The transportation apparatus of claim 21, wherein at least any one of the first area or the second area has a size different from that of the third area.
